(19) United States
(12) Patent Application Publication
(10) Pub. No.: US 2025/0311310 A1
(43) Pub. Date: Oct. 2, 2025

(54) PLANAR FERROELECTRIC MAJORITY GATES

(71) Applicant: Intel Corporation, Santa Clara, CA (US)

(72) Inventors: Karam Cho, Hillsboro, OR (US); Hai Li, Portland, OR (US); Dmitri Evgenievich Nikonov, Beaverton, OR (US); Ian Alexander Young, Olympia, WA (US); Raseong Kim, Portland, OR (US)

(73) Assignee: Intel Corporation, Santa Clara, CA (US)

(21) Appl. No.: 18/622,832

(22) Filed: Mar. 29, 2024

(51) Int. Cl. H01L 29/78; H01L 25/18; H01L 27/02; H01L 29/51

(52) U.S. Cl. CPC H10D 30/701; H01L 25/18; H10D 64/689; H10D 89/10

(57) ABSTRACT

Technologies for planar three-input ferroelectric majority gates are disclosed. In one embodiment, a ferroelectric layer has asymmetric input electrodes and an output electrode located on a surface of the ferroelectric layer. When a voltage is applied to each input, the inputs and a ground plane below the ferroelectric layer form a capacitor. The ferroelectric layer becomes polarized based on the applied voltages at the inputs. The portion of the ferroelectric layer at the output electrode becomes polarized in the direction of polarization of the majority of the inputs. The output voltage then reflects the majority voltage of the inputs. Symmetric input electrodes are utilized in other ferroelectric majority gate embodiments.

### BACKGROUND

Majority gates, in which an output of the gate is the majority of its inputs, can be used in certain logic circuits. When combined with an inverter, majority gates can be used to create general logic circuits. Majority gates made from conventional CMOS transistors require 12 to 18 MOSFETs.

### BRIEF DESCRIPTION OF THE DRAWINGS

FIG. 1 is a perspective view of a first example planar ferroelectric majority gate with asymmetric input electrodes.

FIG. 2 is a top view of the first example planar ferroelectric majority gate of FIG. 1.

FIGS. 3A and 3B illustrate simulated electrical polarization distributions at top and bottom surfaces of the ferroelectric layer in a second example three-input ferroelectric majority gate.

FIGS. 4A and 4B illustrate simulated electrical polarization distributions at top and bottom surfaces of the ferroelectric layer in a third example three-input ferroelectric majority gate.

FIG. 5 is a perspective view of a fourth example three-input ferroelectric majority gate.

FIGS. 6A-6B illustrate an example majority gate having a substantially circular shape.

FIGS. 6C-6D and 6E-6F illustrate first and second example majority gates, respectively, having an elongated rectangular shape.

FIGS. 6G-6H illustrate a majority gate having a cross shape.

FIGS. 61-6J illustrate a majority gate having an elongated rectangular shape.

FIG. 7 is an example method of forming a three-input ferroelectric majority gate.

FIG. 8 is a top view of a wafer 800 and dies 802 that may include one or more three-input ferroelectric majority gates as disclosed herein.

FIG. 9 is a cross-sectional side view of an integrated circuit device 900 that may be included in any of the processor units, integrated circuit components, or other components disclosed or referenced herein.

FIGS. 10A-10D are perspective views of example planar, FinFET, gate-all-around, and stacked gate-all-around transistors.

FIG. 11 is a cross-sectional side view of an integrated circuit device assembly 1100 that may include a processor unit, integrated circuit component, or other components comprising three-input ferroelectric majority gates.

FIG. 12 is a block diagram of an example electrical device 1200 that may include one or more of integrated circuit components comprising the three-input ferroelectric majority gates disclosed herein.

### DETAILED DESCRIPTION

Described herein are three-input planar ferroelectric majority gates, in which the output of the gate is the majority of its inputs. That is, the output of the gate is logical ‘0’ if the majority of inputs to the gate are logical ‘0’ and the output is logical ‘1’ if the majority of inputs to the gate are logical ‘1’. The majority gates have a capacitor structure and comprise a planar ferroelectric layer, three input electrodes and an output electrode located on a top surface of the ferroelectric layer, and a bottom electrode located on the bottom surface of the ferroelectric layer. With the bottom electrode grounded and input voltages applied to the input electrodes, the ferroelectric layer becomes polarized based on the applied voltages at the inputs. The portion of the ferroelectric layer at the output electrode becomes polarized in the direction of polarization of the majority of the inputs. The output voltage then reflects the majority voltage of the inputs.

In some embodiments, the ferroelectric layer has a square shape, the input electrodes are arranged in a triangle configuration, the output electrode is located at a center of the triangle, and the input electrodes are asymmetric. The input electrodes are asymmetric in that one of the input electrodes has a length that matches that of the other input electrodes but has a width of about half that of the other input electrodes. In other embodiments, the three input electrodes are symmetric in size and shape and the ferroelectric layer has a circular or elongated rectangular shape. A circular ferroelectric majority gate with symmetric electrodes can have input and output electrodes that are circular and arranged in a triangular configuration. Elongated rectangular majority gates can have electrodes that are arranged in a triangular configuration with two input electrodes located at corners on a top surface of the ferroelectric layer and a third input electrode located on an opposite edge from the other two input electrodes of the top surface of the ferroelectric layer. In some elongated rectangular majority gate embodiments, the input and output electrodes are arranged in a row with the output electrode positioned at an end of the row. In other embodiments, the majority gates have a cross shape and have an input electrode on the top surface of each of three ends of the cross-shaped ferroelectric layer, with the fourth electrode located on the top surface of the fourth end of the ferroelectric layer.

The planar ferroelectric majority gates disclosed herein have the advantage of implementing majority gate logic with fewer devices than would be needed using CMOS (Complementary Metal-Oxide-Semiconductor) technology, resulting in a compact majority gate solution that consumes less area and power and may be faster than CMOS implementations.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous.

Terms modified by the word “substantially” include arrangements, orientations, spacings, positions, sizes, and values that vary slightly from the meaning of the unmodified term. For example, a substantially planar layer can have bumps and dips on its surface due to manufacturing process imperfections, and shapes that are indicated as being substantially circular, substantially an isosceles triangle, substantially a square, etc. include shapes that deviate from the ideal form of the unmodified term due to processing limitations and variations. Features that are indicated as being substantially at a position or location include features that are offset from the indicated position or located by several nanometers, and dimensions or features of components such as widths, lengths, sizes, and lateral areas that are indicated as being substantially equal include dimensions and features of components that are within +/−10% of each other. Values modified by the word “about” include values within +/−10% of the listed values and values listed as being within a range include those within a range from 10% less than the listed lower range limit and 10% greater than the listed higher range limit.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

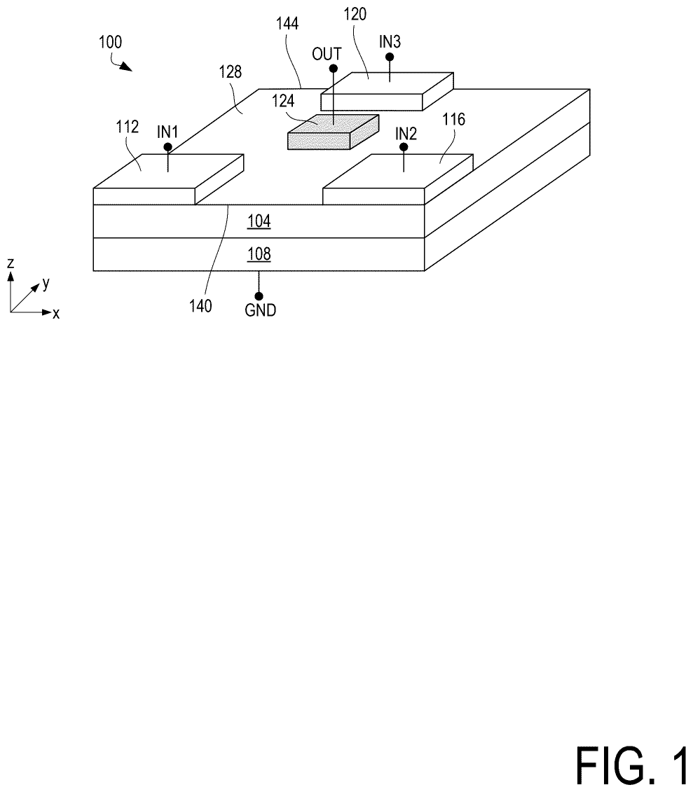

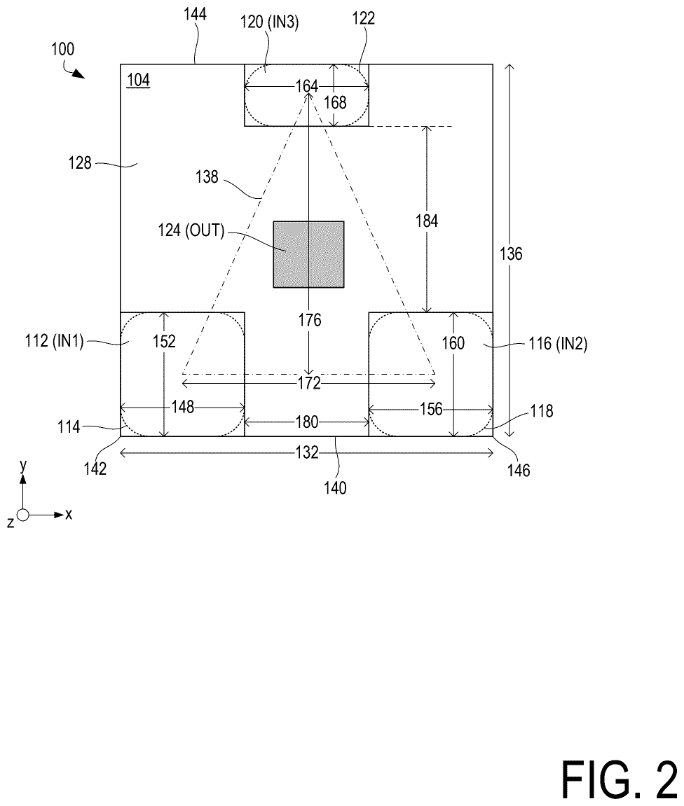

FIGS. 1 and 2 are perspective and top views, respectively of a first example planar ferroelectric majority gate with asymmetric input electrodes. The gate 100 comprises a layer 104 comprising a ferroelectric material positioned between a bottom electrode 108 and input electrodes 112 (IN1), 116 (IN2), and 120 (IN3) and output electrode 124 (OUT). Output electrodes are shaded grey in the Figures. The ferroelectric layer 104 is substantially planar and is located on the bottom electrode 108. The input electrodes 112, 116, and 120 and output electrode 124 are positioned on a top surface 128 of the ferroelectric layer 104. The gate 100 has a substantially square shape when viewed from above and has a length 132 and a width 136. The input electrodes 112, 116, and 120 are arranged in a triangular configuration. Input electrodes 112 and 116 are positioned at adjacent corners 142 and 146 along an edge 140 of the top surface 128 and input electrode 120 is positioned at a midpoint of an edge 144 of the top surface 128 that is opposite to the edge 140. The output electrode 124 is positioned within a triangle 138 that has as its vertices the centers of electrodes 112, 116, and 120. The output electrode 124 can be located at a center of the triangle 138, such as its centroid, incircle, or circumcenter. In some embodiments, the output electrode 124 is not located exactly at one of these centers of the triangle 138 but is in the vicinity of one of these centers (e.g., within several nanometers of these centers, or within a different distance of one of these centers depending on the manufacturing tolerances and/or process biases of the manufacturing technology used to fabricate the majority gate 100). In other embodiments, the output electrode 124 is positioned at the center of the ferromagnet layer 104.

The input electrodes 112, 116, and 120 are asymmetric in that they are not all the same size. Electrode 112 has a length 148 and a width 152, electrode 116 has a length 156 and a width 160, and electrode 120 has a length 164 and a width 168. The widths 148, 156, and 164 are substantially the same, as are the widths 152 and 160. Thus, the electrodes 112 and 116 are substantially the same size and have substantially equal lateral areas (the area of the electrode in the x- and y-dimensions). However, the width 168 of electrode 120 is about half that of widths 152 and 160 of electrodes 112 and 116. As a result of this electrode size asymmetry, the triangle 138 is an isosceles triangle having a base 172 and height 176, the base 172 being less than the height 176. This asymmetry also results in a spacing 180 between electrodes 112 and 116 being less than a spacing 184 between electrodes 116 (or 112) and 120. In some embodiments, the output electrode 124 can be about the same size as or smaller than any of the input electrodes, such as 10%, 20%, 30%, or another percentage smaller. In some embodiments, the lengths 148, 156, and 164 of the input electrodes 112, 116, 120 are substantially one-third the width of the ferroelectric layer.

The input and output electrode shapes illustrated in the Figures are idealized electrode shapes, such as the electrode shapes as they might be drawn an electronic design automation (EDA) tool (e.g., a layout tool). Due to manufacturing limitations and process biases, the as-processed shapes of the input and output electrodes may differ from those illustrated in the Figures. For example, with reference to FIG. 2, square input electrodes 112, 116, and 120 may have associated as-processed shapes 114, 118, and 122 that have rounded corners. The difference between the shapes of the input electrodes as drawn in an EDA tool and their associated as-processed shapes can vary depending on the size of the input electrodes relative to the minimum feature size capability of the photolithography process being used during formation of the electrodes as well as other manufacturing limitations and processes biases. Regardless, the length and width of an electrode, as those terms are used herein, pertain to the length and width of the electrode regardless of its as-processed shape (e.g., square, square with rounded edges, oval, ellipse, circle). For as-processed electrodes that are circular, the terms length and width can refer to the electrode's diameter.

Table 1 shows the truth table implemented by the three-input ferroelectric majority gates described herein. If a majority of the inputs (two or three) are logical ‘0’, the output is logical ‘0’. If a majority of the inputs are logical ‘1’, the output is logical ‘1’. The ferroelectric majority gates disclosed herein operate as follows. Input signals are applied by setting the bottom electrode to ground (or other reference voltage) and applying input voltages to the input electrodes. Application of a positive voltage (+Vin) represents a logical ‘1’ and application of a negative voltage (−Vin) represents a logical ‘0’. The output of the majority gate is represented by the electrical polarization in the region of the ferroelectric layer located at the output contact.

A logical ‘0’ input (−Vin) applied to an input electrode induces a positive electrical polarization in the ferroelectric layer and a logical ‘1’ input (+Vin) applied to an input electrode induces a negative polarization. The electrical polarization in the ferroelectric layer in the region where the output electrode is located is based on the interaction of the polarization domains that are directly switched by the input voltages. The majority gate functionality is realized in the electrical polarization in the region of the ferroelectric layer located at the output electrode. The electrical polarization in the region of the ferroelectric layer at the output electrode is positive if a negative voltage is applied to a majority of the input electrodes and negative if a positive voltage is applied to a majority of the input electrodes.

TABLE 1
Truth Table for three-input ferroelectric majority gate

| | No. of | | Output |
|---|---|---|---|
| Input | inputs with | Majority | (polarization in |
| (IN1, IN2, IN3) | logical ‘1’ | Logic | ferroelectric layer) |
| (0, 0, 0) | 0 | ‘0’ | +polarization |
| (0, 0, 1) | 1 | ‘0’ | +polarization |
| (0, 1, 0) | 1 | ‘0’ | +polarization |
| (1, 0, 0) | 1 | ‘0’ | +polarization |
| (0, 1, 1) | 2 | ‘1’ | −polarization |
| (1, 1, 0) | 2 | ‘1’ | −polarization |
| (1, 0, 1) | 2 | ‘1’ | −polarization |
| (1, 1, 1) | 3 | ‘1’ | −polarization |

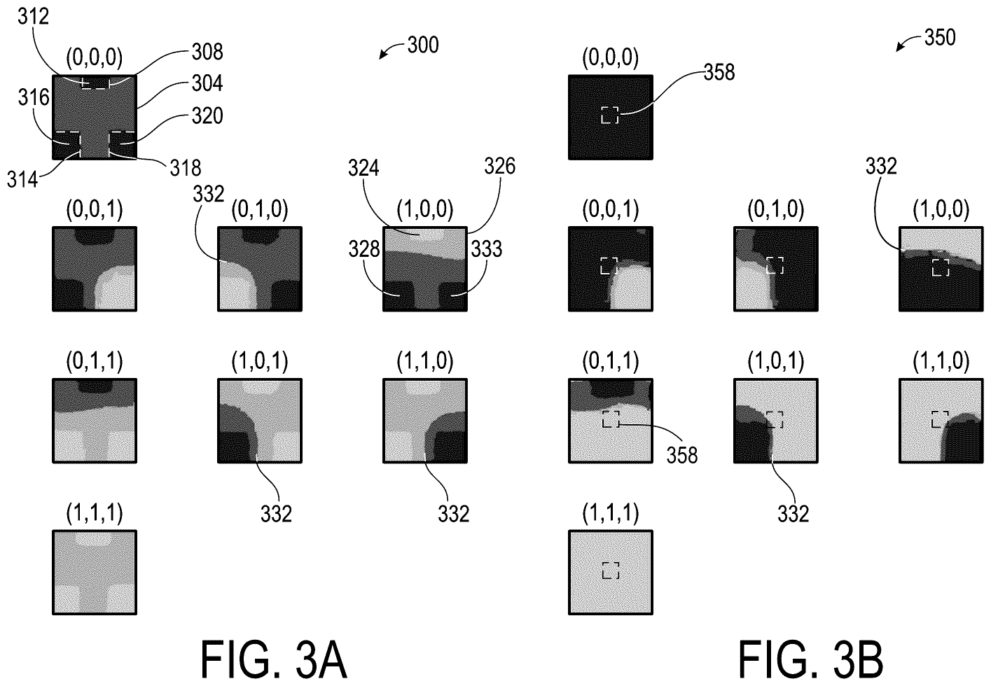

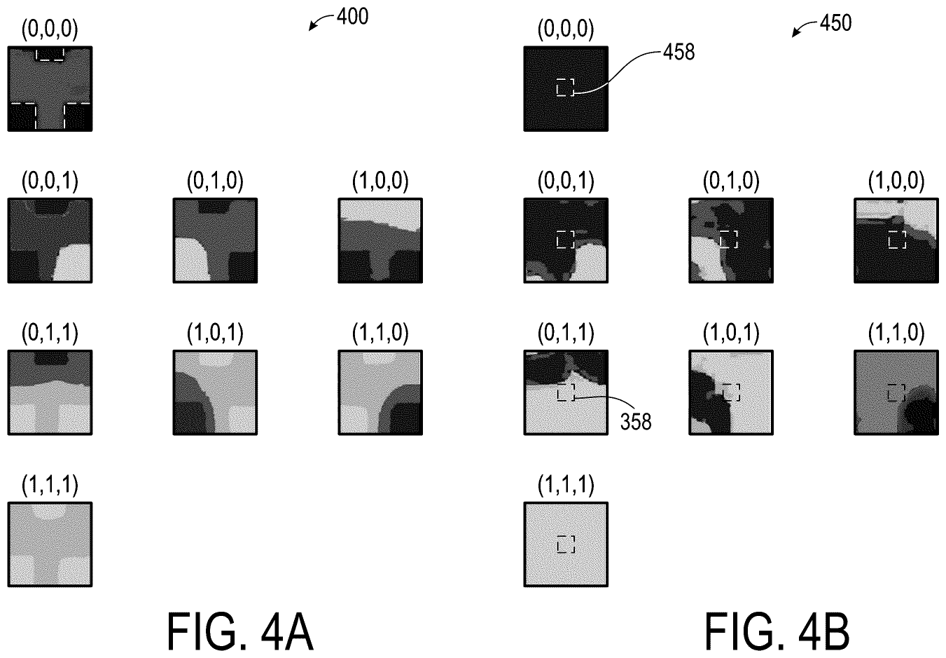

FIGS. 3A and 3B illustrate simulated electrical polarization distributions at top and bottom surfaces of a ferroelectric layer in a second example three-input ferroelectric majority gate. The polarization distributions 300 and 350 illustrated in FIGS. 3A and 3B are for a majority gate having the structure illustrated in FIGS. 1 and 2, with the square ferroelectric layer made of bismuth ferrite (BiFeO₃) and having a length and width of ten nanometers and a thickness of two nanometers. In the polarization distributions shown in FIGS. 3A-3B and 4A-4B, the first, second, and third values in the triplet at the top of each polarization distribution indicate the logical values applied to the top, lower left, and lower right input electrodes, respectively. For example, with reference to distribution 304 in FIG. 3A, the triplet (0,0,0) indicates that a logical ‘0’ is applied to the top input electrode 312, the lower left input electrode 316, and the lower right input electrode 320. The dashed lines 308, 314, and 318 in distribution 304 represent the physical boundaries of the input electrodes 312, 316, and 320, respectively, and the locations of the electrodes are indicated by the strong positive and negative polarizations in the other distributions, such as regions 324, 328, and 333 in distribution 326 indicating the locations of input electrodes 312, 316, and 320. The simulation results illustrated in FIGS. 3A-3B and 4A-4B are based on simulations where input voltages are applied by first grounding the bottom layer (which can be referred to as a ground layer or ground electrode) and applying +10 V and −10 V for the logical ‘1’ and ‘0’ values, respectively. Other suitable input voltages can be used in other embodiments. The location of the output electrodes is indicated by the dashed lines 358 in FIG. 3B. Even though the location of the output electrode is indicated in the distributions 350 showing the polarization at the bottom surface of the ferroelectric layer, the output electrode of the majority gates simulated to produce the distributions illustrated in FIGS. 3A-3B and 4A-4B are located on the top surface of the ferroelectric layer.

In FIGS. 3A-3B and 4A-4B, the dark regions indicate positive polarization and the lighter regions indicate negative polarization. Domain walls 332 (indicated in several of the distributions in FIGS. 3A and 3B) indicate the boundaries between positive and negative polarization domains.

As can be seen in FIGS. 3A and 3B, the ferroelectric layer polarization at the location of the output contact realizes the majority gate function. The simulation results indicate that the triangular configuration of the input contacts and the asymmetric sizes of the input electrodes keep the domain wall away from the location of the output contact for the three-input ferroelectric majority gate design illustrated in FIGS. 1 and 2. The first and second rows of polarization distributions in FIGS. 3A-3B and 4A-4B illustrate distributions where a negative input voltage is applied to a majority of the input electrodes and the polarization at the output electrode is positive. The third and fourth rows of polarizations distributions in FIGS. 3A and 3B illustrate distributions where a positive input voltage is applied to a majority of input electrodes and the polarization at the output electrode is negative.

FIGS. 4A and 4B illustrate simulated electrical polarization distributions at top and bottom surfaces of a ferroelectric layer in a third example three-input ferroelectric majority gate. The polarization distributions 400 and 450 illustrated in FIGS. 4A and 4B are for a majority gate having the majority gate structure illustrated in FIGS. 1 and 2 with a ferroelectric layer made of bismuth ferrite and having a length and width of 29 nanometers and a thickness of six nanometers. That is, the distributions illustrated in FIGS. 4A and 4B are for a majority gate that has the same structure, but is larger than, than majority gate simulated to produce the distributions illustrated in FIGS. 3A and 3B. As can be seen, the polarization distributions illustrated in FIGS. 4A and 4B show the same majority gate behavior at the location of the output contact 458. In other embodiments, a square majority gate having the structure illustrated in FIGS. 1 and 2 can have a length and width other than 10 or 20 nanometers (such as 30 nanometers or less) and a thickness other than six or two nanometers.

The output value of any of the three-input ferroelectric majority gates disclosed herein can be read out using the output electrode. For example, with the bottom electrode grounded, the output value of the majority gate can be indicated by the polarity of the voltage at the output electrode.

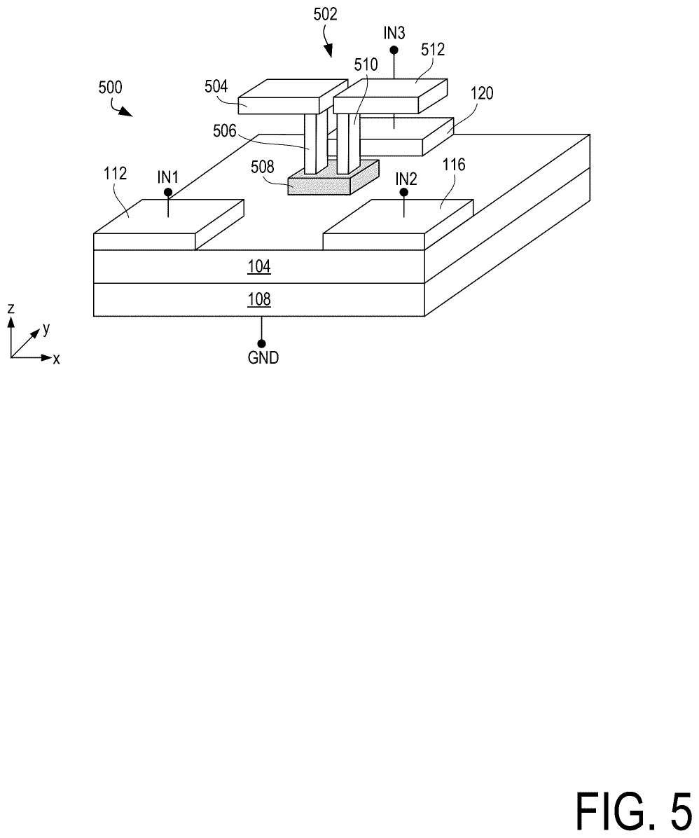

FIG. 5 is a perspective view of a fourth example three-input ferroelectric majority gate. Each of the bottom electrode 104, ferroelectric layer 108, and input electrodes 112, 116, and 120 may be similar to the corresponding component of the majority gate 100 described above, a description of which will not be repeated in the interest of clarity. However, the output 502 in the majority gate 500 is different from the output electrode 124 in the majority gate 100. In the majority gate 500, the output 502 includes several components of a field-effect transistor. The output 502 comprises a source electrode (first output electrode) 504, a source via 506, a channel 508, a drain via 510, and a drain electrode (second output electrode) 512. The polarization of the ferroelectric layer 108 provides the electric field that controls the ability of the channel 508 to conduct. The output 502 may act as a p-MOS or n-MOS transistor, depending on the channel 508.

The source electrode 504, source via 506, drain via 510, and drain electrode 512 may be made of any suitable conductive material. In the illustrative example, the source electrode 504, source via 506, drain via 510, and drain electrode 512 are made of copper. The channel 508 may be made of any suitable material that can interface with the ferroelectric layer 108. For example, the channel 508 may be a transition metal dichalcogenide, germanium oxide, indium oxide, zinc oxide, barium tin oxide, and/or any other suitable material.

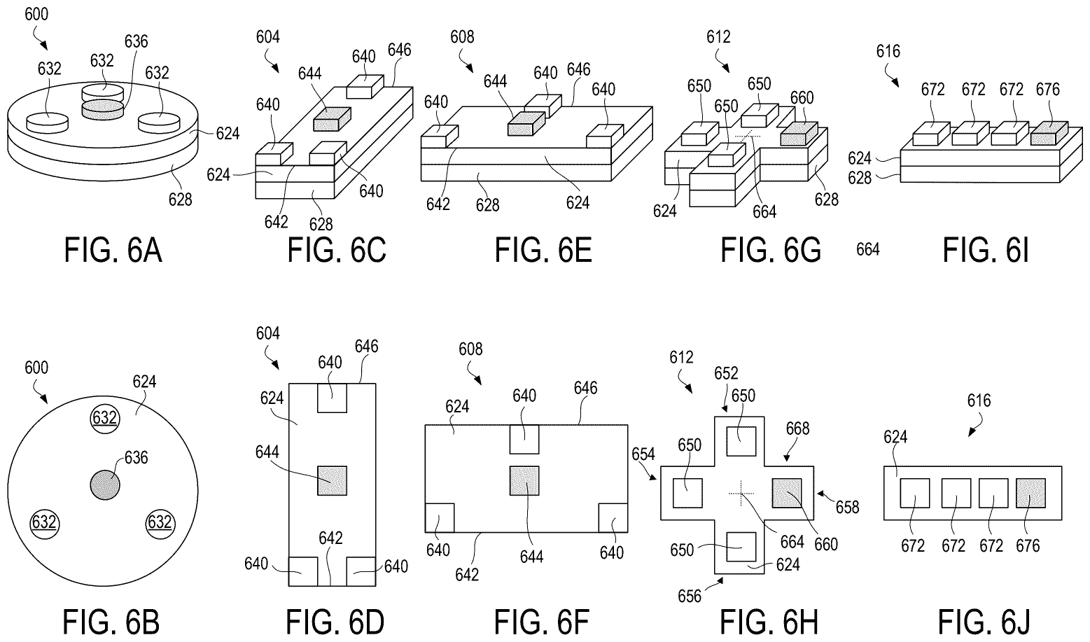

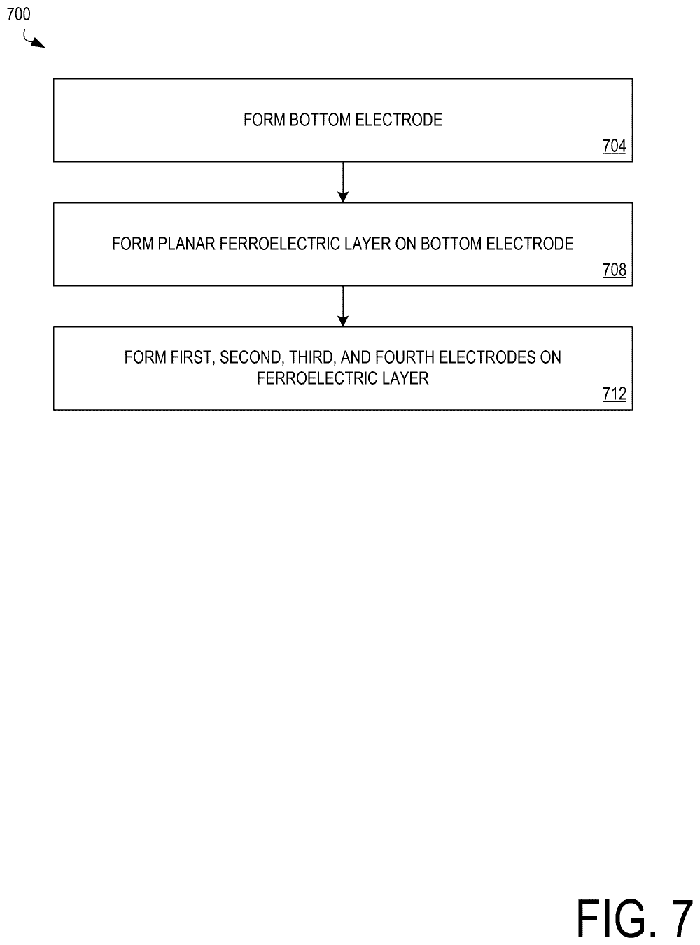

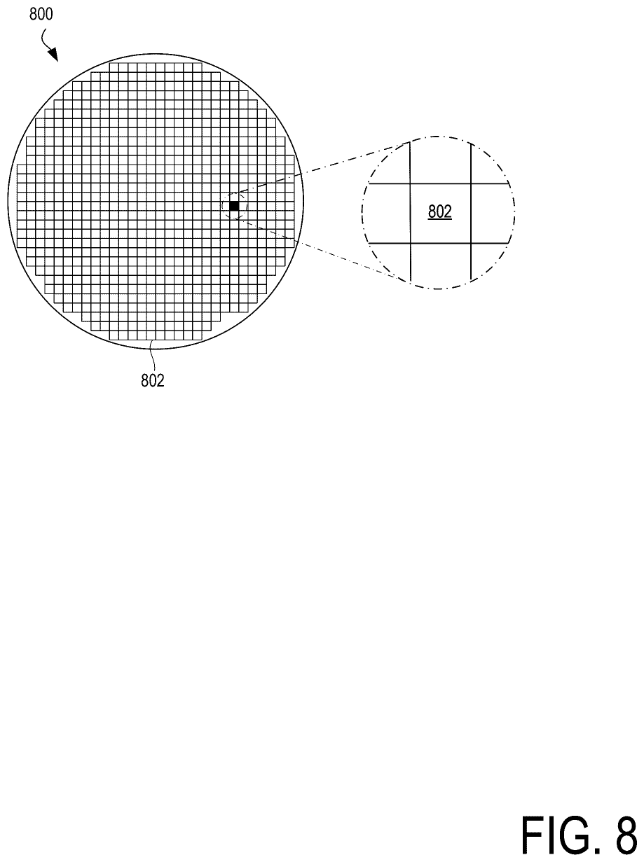

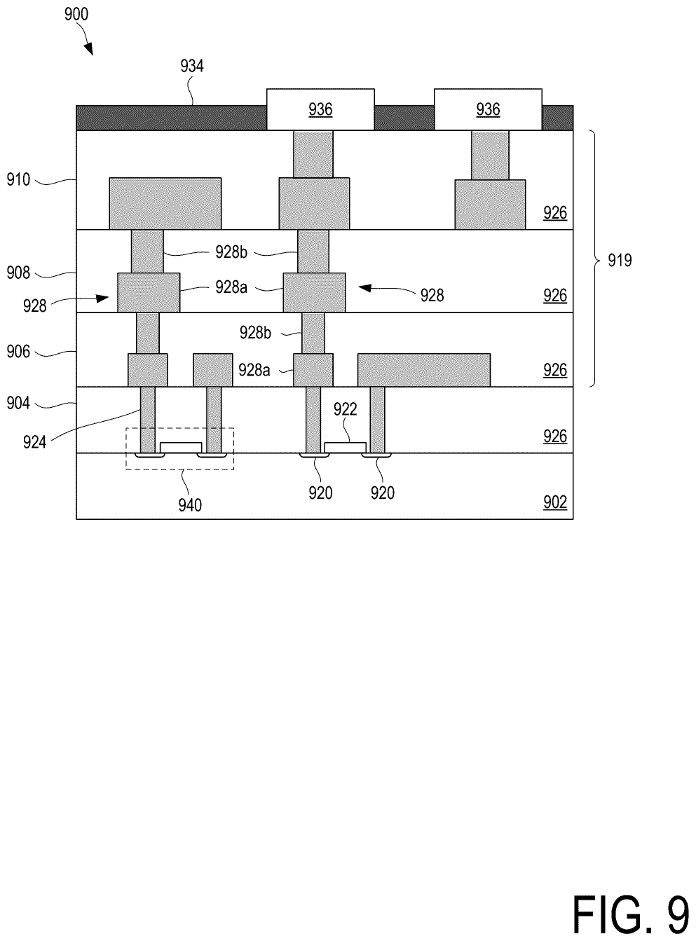

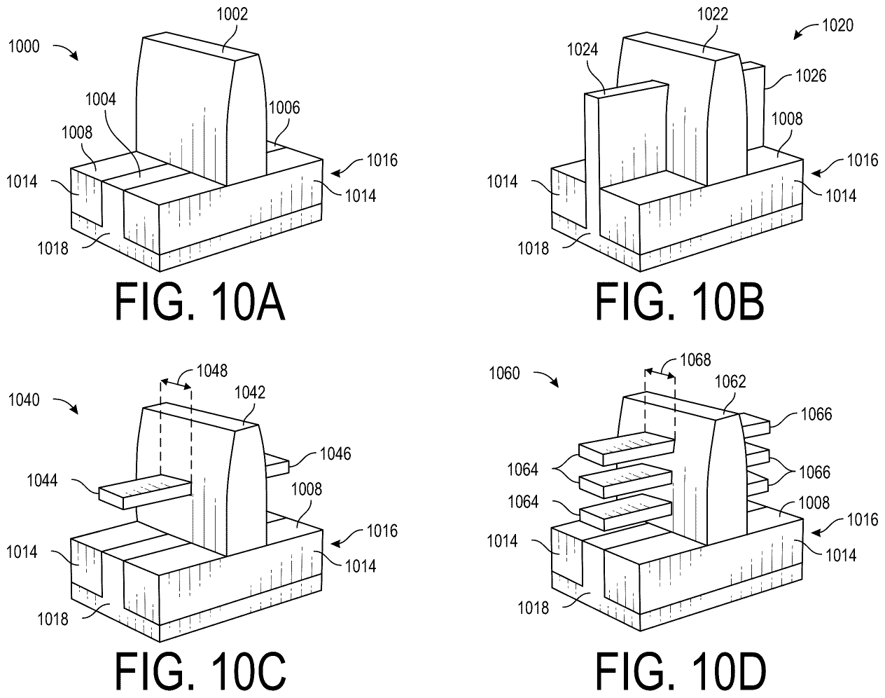

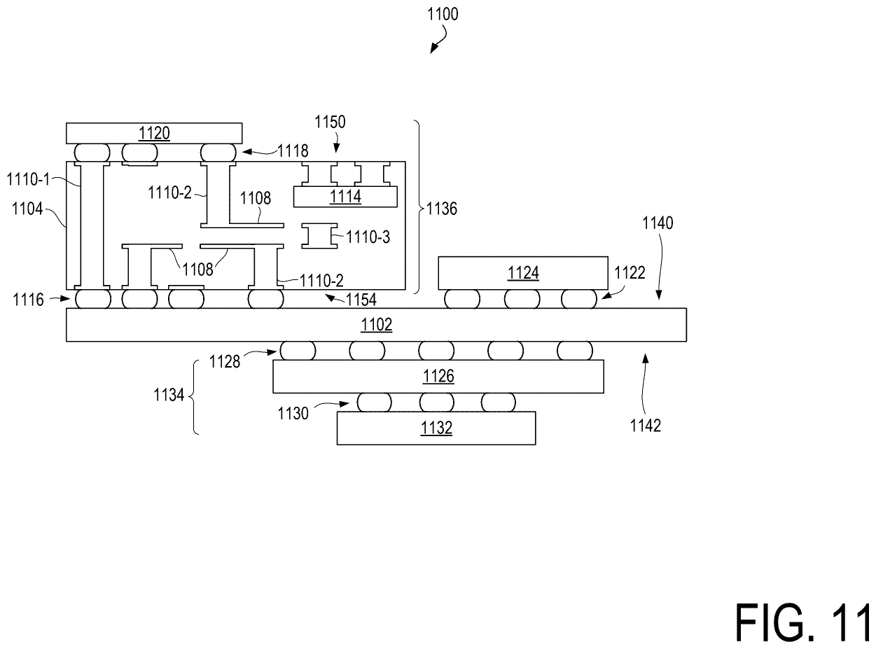

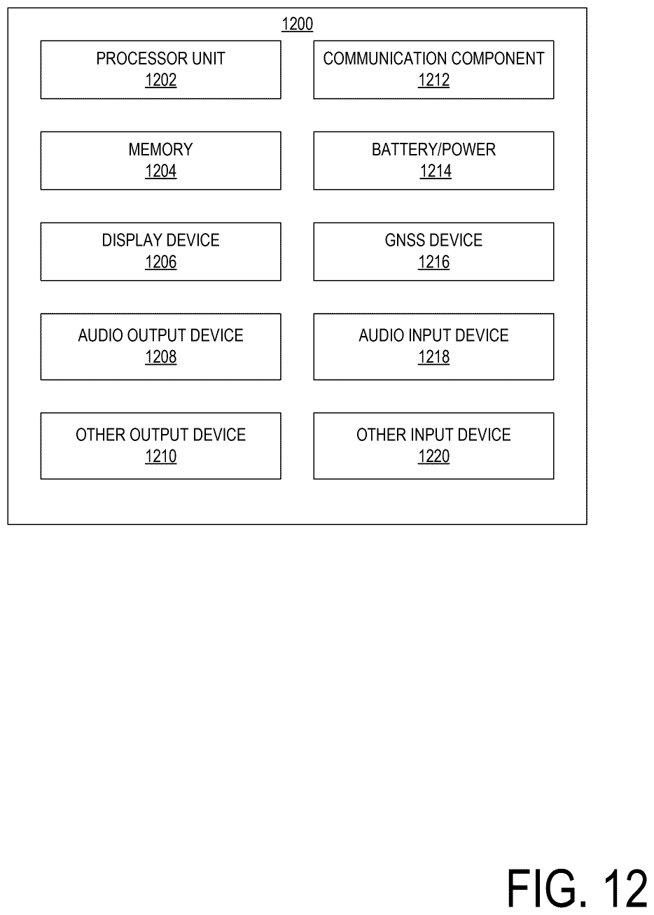

FIGS. 6A-6J illustrate perspective and top views of example three-input ferroelectric majority gates having symmetric input electrodes. Majority gates with symmetric input electrodes may allow for simplified fabrication of the majority gates and less variation in majority gate behavior due to possible manufacturing process variations. The input electrodes of ferroelectric majority gates 600, 604, 608, 612, and 616 are symmetric in they have substantially the same shape and size. The majority gates 600, 604, 608, 612, and 616 each comprise a ferroelectric layer 624 located on a bottom electrode 628. The ferroelectric layers 624 and bottom electrode 628 can be similar to the ferroelectric layer 104 and bottom electrode 108 of majority gate 100 discussed above, the descriptions of which are not repeated for clarity.

FIGS. 6A-6B illustrate an example ferroelectric majority gate comprising a ferroelectric layer 624 and a bottom electrode 628 with a substantially circular shape. The majority gate 600 comprises substantially circular input and output electrodes 632 and 636 located on a top surface of the ferroelectric layer 624.

FIGS. 6C-6D and 6E-6F illustrate first and second example ferroelectric majority gates having an elongated rectangular shape. The majority gates 604 and 608 each comprise input electrodes 640 and an output electrode 644 located on a top surface of the ferroelectric layer 624. Two of the input electrodes are located at adjacent corners along a first edge 642 of the top surface of the ferroelectric layer 624 and the third input electrode 640 is located at a midpoint along a second edge 646 of the top surface of the ferroelectric layer 624. The second edge 646 is opposite to the first edge 642. The majority gate 604 is elongated in a direction substantially orthogonal to the direction that the first edge 642 extends and the majority gate 608 is elongated in the direction that the first edge 642 extends.

The input electrodes of the majority gates 600, 604, and 608 are arranged in a triangle configuration. The output electrode of each of these majority gates is positioned within a triangle that has the centers of the input electrodes as its vertices. The output electrode can be positioned at a center of this, such as its centroid, incircle, or circumcenter. In some embodiments, the output electrode of majority gates 600, 604, and 608 is not located exactly at one of these centers but is in the vicinity of one of these centers.

FIGS. 6G-6H illustrate a ferroelectric majority gate 612 having a cross shape. The majority gate 612 comprises an input electrode 650 at ends of the cross-shaped ferroelectric layer 624 (ends 652, 654, and 656) and an output electrode 660 at the fourth end 658. The input electrodes 650 and the output electrode 660 are substantially equidistant from a center 664 of the gate 612. In other embodiments, the output electrode 660 can be positioned at any point from the center 664 of the gate to an end of a leg of the gate (e.g., any point along leg 668). The leg of the gate upon which the output electrode 660 is positioned can have a different length than the lengths of the legs upon which the input electrodes 650 are located.

FIGS. 6I-6J illustrate a third majority gate 604 having an elongated rectangular shape. The majority gate 616 comprises input electrodes 672 and output electrode 676 arranged in a row with the output electrode 676 positioned at an end of the row.

In some embodiments, the input electrodes of majority gates 600, 604, 608, 612, and 616 can be asymmetric. That is, any of the input electrodes can have a different shape or size (e.g., length, width, radius, or other dimension) that is different from the shape or size of the other two input electrodes. For example, the input electrode 640 positioned adjacent to edges 646 in majority gates 604 and 608 can have a width or length that is less than that of the other input electrodes.

Any of the three-input majority gates described herein can be located on or above a substrate. In some embodiments, the substrate can comprise silicon or silicon dioxide (SiO₂).

It should be appreciated that the embodiments described above show a single majority gate. However, in use, the majority gates can be connected together or connected to other logic components (e.g., inverters or transistors) to form more complex logic circuitry, such as a processor.

The ferroelectric layer of any majority gate described herein can comprise a suitable ferroelectric material, such as barium titanate (BaTiO₃, also known as BTO, which is a material comprising barium, titanium, and oxygen), bismuth ferrite (BiFeO₃, also referred to as BFO, which is a material that comprises bismuth, iron, and oxygen), samarium-doped BFO (Sm-doped BFO), lanthanum-doped BFO (La-doped BFO), barium strontium titanate ((Ba,Sr)TiO₃, which is a material comprising barium, strontium, titanium, and oxygen), lithium tantalate (LiTaO₃, which is a material comprising lithium, tantalum, and oxygen), lead titanate (PbTiO₃, also known as PTO, which is a material comprising lead, titanium, and oxygen), lead strontium titanate (Pb₁₋ₓSrₓTiO₃, also known as PST, which is a material comprising lead, strontium, titanium, and oxygen), lead zirconate titanate (Pb(ZrₓTi₁₋ₓ)O₃, also known as PZT, which is a material that comprises lead, zirconium, titanium, and oxygen), lead lanthanum zirconate titante ((Pb,La)(Zr,Ti)O₃, also known as PLZT, which is a material comprising lead, lanthanum, zirconium, titanium and oxygen), lead nickel zirconate titanate ((Pb,Ni)(Zr,Ti) O₃, also known as PNZT, which is a material comprising lead, nickel, zirconium, titanium, and oxygen), sodium tantalate (NaTaO₃, which is a material comprising sodium, tantalum, and oxygen), strontium titanate (SrTiO₃, also known as STO, which is a material comprising strontium, titanium, and oxygen), potassium tantalate (KTaO₃, also known as KTO, which is a material comprising potassium, tantalum, and oxygen), lithium tantalate (LiTaO₃, also known as LTO, which is a material comprising lithium, tantalum, and oxygen), bismuth iron cobalt oxide (BiFe₁₋ₓCoₓO₃, which is a material comprising bismuth, iron, cobalt, and oxygen), potassium niobate (KNiO₃, which is a material comprising potassium, niobium, and oxygen), calcium niobium titanate (CaNbTi₂O₆, which is a material comprising calcium, niobium, titanium, and oxygen), lead bismuth niobate (Pb₂BiNbO₆, which is a material comprising lead, bismuth, niobium, and oxygen), calcium niobium nitride oxide (Ca₃Nb₂N₂O₅, which is a material comprising calcium, niobium, nitrogen, and oxygen), bismuth titanate (Bi₄Ti₃O₁₂, which is a material comprising bismuth, titanium, and oxygen), barium hafnium titanium oxide (Ba(Hf,Ti)O₃, which is a material comprising barium, hafnium, titanium, and oxygen), barium calcium zirconium titanium oxide (Ba,Ca)(Zr,Ti)O₃ (which is a material comprising barium, calcium, zirconium, titanium, and oxygen), gadolinium ferrate (GdFeO₃, which is a material comprising gadolinium, iron, and oxygen), gadolinium lanthanum iron oxide (Ga,La)FeO₃ (which is a material comprising gadolinium, lanthanum, iron, and oxygen), barium calcium titanium oxide (Ba,Ca)TiO₃ (which is a material comprising barium, calcium, titanium, and oxygen), or barium zirconium titanium oxide Ba(Zr,Ti)O₃ (which is a material comprising barium, zirconium, titanium, and oxygen).

The bottom, input and output electrodes of any majority gate described herein can be any suitable conducting material that can directly or indirectly interface with the ferroelectric layer of the gate, such as lanthanum strontium manganite (La₍₁₋ₓ₎Sr₍ₓ₎MnO₃, also known as LSMO, a material comprising lanthanum, strontium, manganese, and oxygen)), niobium-doped strontium titanate (Nb,SrTiO₃, also known as Nb-STO, a material comprising niobium, strontium, titanium, and oxygen), SrRuO₃ (also known as SRO, a material comprising strontium, ruthenium, and oxygen), or copper.

FIG. 7 is an example method of forming a planar ferroelectric majority gate comprises the method 700 can be performed by an integrated circuit manufacturer. At 704, a bottom electrode comprising a first material is formed. At 708, a layer is formed on the bottom electrode, the layer substantially planar and comprising a ferroelectric material, a top surface of the bottom electrode having a square shape. At 712, a first electrode, a second electrode, a third electrode, and a fourth electrode are formed on the top surface of the layer, the first electrode and the second electrode located at adjacent corners along a first edge of the top surface, the third electrode located at a midpoint of a second edge of the layer, the second edge opposite to the first edge, the first electrode having a first length and a first width, the second electrode having a second length and a second width, the third electrode having a third length and a third width, the first length, the first width, the second length, the second width, and the third length substantially equal, the third width less than the first width, the fourth electrode located on the top surface of the layer, the fourth electrode positioned within a triangle having as its vertices a center of the first electrode, a center of the second electrode, and a center of the third electrode.

The majority gates described herein can be used in any processor unit or integrated circuit component described or referenced herein. An integrated circuit component comprising the planar majority gates can be attached to a printed circuit board. In some embodiments, one or more additional integrated circuit components or other components, such as a battery or antenna, can be attached to the printed circuit board. In some embodiments, the printed circuit board and the integrated circuit component can be located in a computing device that comprises a housing that encloses the printed circuit board and the integrated circuit component. An integrated circuit structure comprising devices that include ferroelectric majority gates can comprise other types of devices, such as electronic transistors (transistors such as CMOS transistors that operate through control of the flow of electric current and that do not rely upon the switching of the magnetization of a layer or component for operation).

FIG. 8 is a top view of a wafer 800 and dies 802 that may include one or more three-input ferroelectric majority gates as disclosed herein. The wafer 800 may be composed of semiconductor material and may include one or more dies 802 having integrated circuit structures formed on a surface of the wafer 800. The individual dies 802 may be a repeating unit of an integrated circuit product that includes any suitable integrated circuit. After the fabrication of the integrated circuit product is complete, the wafer 800 may undergo a singulation process in which the dies 802 are separated from one another to provide discrete “chips” of the integrated circuit product. The die 802 may be any of the processing units or integrated circuit components disclosed herein. The die 802 may include one or more transistors (e.g., some of the electronic transistors 940 of FIG. 9, discussed below, spintronic transistors, supporting circuitry to route electrical signals to the transistors, passive components (e.g., signal traces, resistors, capacitors, or inductors), and/or any other integrated circuit components. In some embodiments, the wafer 800 or the die 802 may include a memory device, a logic device (e.g., an AND, OR, Nand, or NOR gate), or any other suitable circuit element. Multiple ones of these devices may be combined on a single die 802. For example, a memory array formed by multiple memory devices may be formed on a same die 802 as a processor unit (e.g., the processor unit 1202 of FIG. 12) or other logic that is configured to store information in the memory devices or execute instructions stored in the memory array. Various microelectronic assemblies may be manufactured using a die-to-wafer assembly technique in which some dies are attached to a wafer 800 that includes others of the dies, and the wafer 800 is subsequently singulated.

FIG. 9 is a cross-sectional side view of an integrated circuit device 900 that may be included in any of the processor units, integrated circuit components or other components disclosed or referenced herein. One or more of the integrated circuit devices 900 may be included in one or more dies 802 (FIG. 8). The integrated circuit device 900 may be formed on a die substrate 902 (e.g., the wafer 800 of FIG. 8) and may be included in a die (e.g., the die 802 of FIG. 8). The die substrate 902 may be a semiconductor substrate composed of semiconductor material systems including, for example, n-type or p-type materials systems (or a combination of both). The die substrate 902 may include, for example, a crystalline substrate formed using a bulk silicon or a silicon-on-insulator (SOI) substructure. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit device 900 may be used. The die substrate 902 may be part of a singulated die (e.g., the dies 802 of FIG. 8) or a wafer (e.g., the wafer 800 of FIG. 8).

The integrated circuit device 900 may include one or more device layers 904 disposed on the die substrate 902. The device layer 904 may include features of one or more electronic transistors 940 (e.g., metal oxide semiconductor field-effect transistors (MOSFETs)) formed on the die substrate 902. The transistors 940 may include, for example, one or more source and/or drain (S/D) regions 920, a gate 922 to control current flow between the S/D regions 920, and one or more S/D contacts 924 to route electrical signals to/from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors. The integrated circuit device 900 can further include spintronic devices, such as the MESO devices described herein.

FIGS. 10A-10D are simplified perspective views of example planar, FinFET, gate-all-around, and stacked gate-all-around field-effect transistors. The transistors illustrated in FIGS. 10A-10D are formed on a substrate 1016 having a surface 1008. Isolation regions 1014 separate the source and drain regions of the transistors from other transistors and from a bulk region 1018 of the substrate 1016.

FIG. 10A is a perspective view of an example planar transistor 1000 comprising a gate 1002 that controls current flow between a source region 1004 and a drain region 1006. The transistor 1000 is planar in that the source region 1004 and the drain region 1006 are planar with respect to the substrate surface 1008.

FIG. 10B is a perspective view of an example FinFET transistor 1020 comprising a gate 1022 that controls current flow between a source region 1024 and a drain region 1026. The transistor 1020 is non-planar in that the source region 1024 and the drain region 1026 comprise “fins” that extend upwards from the substrate surface 1008. As the gate 1022 encompasses three sides of the semiconductor fin that extends from the source region 1024 to the drain region 1026, the transistor 1020 can be considered a tri-gate transistor. FIG. 10B illustrates only one S/D fin extending through the gate 1022, but multiple S/D fins can extend through the gate of a FinFET transistor.

FIG. 10C is a perspective view of a gate-all-around (GAA) transistor 1040 comprising a gate 1042 that controls current flow between a source region 1044 and a drain region 1046. The transistor 1040 is non-planar in that the source region 1044 and the drain region 1046 are elevated from the substrate surface 1028.

FIG. 10D is a perspective view of a GAA transistor 1060 comprising a gate 1062 that controls current flow between multiple elevated source regions 1064 and multiple elevated drain regions 1066. The transistor 1060 is a stacked GAA transistor as the gate controls the flow of current between multiple elevated S/D regions stacked on top of each other. The transistors 1040 and 1060 are considered gate-all-around transistors as the gates encompass all sides of the semiconductor portions that extend from the source regions to the drain regions. The transistors 1040 and 1060 can alternatively be referred to as nanowire, nanosheet, or nanoribbon transistors depending on the width (e.g., widths 1048 and 1068 of transistors 1040 and 1060, respectively) of the semiconductor portions extending through the gate.

Returning to FIG. 9, a transistor 940 may include a gate 922 formed of at least two layers, a gate dielectric, and a gate electrode (or conductive trace). The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 940 along the source-channel-drain direction, the gate electrode may consist of a U-shaped structure that includes a bottom portion substantially parallel to the surface of the die substrate 902 and two sidewall portions that are substantially perpendicular to the top surface of the die substrate 902. In other embodiments, at least one of the metal layers that form the gate electrode may simply be a planar layer that is substantially parallel to the top surface of the die substrate 902 and does not include sidewall portions substantially perpendicular to the top surface of the die substrate 902. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of individual transistors 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the integrated circuit device 900.

The interconnect structures 928 may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuit devices having more or fewer interconnect layers than depicted.

In some embodiments, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page from the perspective of FIG. 9. The vias 928b may be arranged to route electrical signals in a direction of a plane that is substantially perpendicular to the surface of the die substrate 902 upon which the device layer 904 is formed. In some embodiments, the vias 928b may electrically couple lines 928a of different interconnect layers 906-910 together.

The interconnect layers 906-910 may include a dielectric material 926 disposed between the interconnect structures 928, as shown in FIG. 9. The dielectric material 926 disposed between the interconnect structures can be referred to as an inter-layer dielectric (ILD). In some embodiments, dielectric material 926 disposed between the interconnect structures 928 in different ones of the interconnect layers 906-910 may have different compositions; in other embodiments, the composition of the dielectric material 926 between different interconnect layers 906-910 may be the same. In some embodiments, dielectric 926 the interconnect structures 928 can comprise a perovskite material. The device layer 904 may include a dielectric material 926 disposed between the transistors 940 and a bottom layer of the metallization stack as well. The dielectric material 926 included in the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910. The one or more interconnect layers 906-910 plus the dielectric layers between the interconnect layers 706-710 may form a metallization stack (also referred to as an “ILD stack” (inter-layer dielectric stack)) 919 of the integrated circuit device 900.

A first interconnect layer 906 (referred to as Metal 1 or “M1”) may be formed directly on the device layer 904. In some embodiments, the first interconnect layer 906 may include lines 928a and/or vias 928b, as shown. The lines 928a of the first interconnect layer 906 may be coupled with contacts (e.g., the S/D contacts 924) of the device layer 904. The vias 928b of the first interconnect layer 906 may be coupled with the lines 928a of a second interconnect layer 908.

The second interconnect layer 908 (referred to as Metal 2 or “M2”) may be formed directly on the first interconnect layer 906. In some embodiments, the second interconnect layer 908 may include via 928b to couple the lines 928 of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit device 900 (i.e., farther away from the device layer 904) may be thicker that the interconnect layers that are lower in the metallization stack 919, with lines 928a and vias 928b in the higher interconnect layers being thicker than those in the lower interconnect layers.

In some embodiments, MESO devices can be fabricated within the ILD stack. That is, a MESO device can be fabricated between adjacent interconnect layers (e.g., between Metal 2 and Metal 3 layers) or non-adjacent interconnect layers. A via can be used to connect a MESO device electrode to an interconnect. In some embodiments, a MESO device electrode can connect to an interconnect layer by being positioned adjacent to an interconnect layer.

The integrated circuit device 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to external devices. For example, solder bonds may be formed on the one or more conductive contacts 936 to mechanically and/or electrically couple an integrated circuit die including the integrated circuit device 900 with another component (e.g., a printed circuit board). The integrated circuit device 900 may include additional or alternate structures to route the electrical signals from the interconnect layers 906-910; for example, the conductive contacts 936 may include other analogous features (e.g., posts) that route the electrical signals to external components.

In some embodiments in which the integrated circuit device 900 is a double-sided die, the integrated circuit device 900 may include another metallization stack (not shown) on the opposite side of the device layer(s) 904. This metallization stack may include multiple interconnect layers as discussed above with reference to the interconnect layers 906-910, to provide conductive pathways (e.g., including conductive lines and vias) between the device layer(s) 904 and additional conductive contacts (not shown) on the opposite side of the integrated circuit device 900 from the conductive contacts 936.

In other embodiments in which the integrated circuit device 900 is a double-sided die, the integrated circuit device 900 may include one or more through silicon vias (TSVs) through the die substrate 902; these TSVs may contact the device layer(s) 904 and may provide conductive pathways between the device layer(s) 904 and additional conductive contacts (not shown) on the opposite side of the integrated circuit device 900 from the conductive contacts 936. In some embodiments, TSVs extending through the substrate can be used for routing power and ground signals from conductive contacts on the opposite side of the integrated circuit device 900 from the conductive contacts 936 to the transistors 940 and any other components integrated into the die 900, and the metallization stack 919 can be used to route I/O signals from the conductive contacts 936 to transistors 940 and any other components integrated into the die 900.

Multiple integrated circuit devices 900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 11 is a cross-sectional side view of an integrated circuit device assembly 1100 that may include a processor unit, integrated circuit component, or other components comprising three-input ferroelectric majority gates. The integrated circuit device assembly 1100 includes a number of components disposed on a circuit board 1102 (which may be a motherboard, system board, mainboard, etc.). The integrated circuit device assembly 1100 includes components disposed on a first face 1140 of the circuit board 1102 and an opposing second face 1142 of the circuit board 1102; generally, components may be disposed on one or both faces 1140 and 1142.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. The integrated circuit device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpacked integrated circuit product that includes one or more integrated circuit dies (e.g., the die 802 of FIG. 8, the integrated circuit device 900 of FIG. 9) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1120, a single monolithic integrated circuit die comprises solder bumps attached to contacts on the die. The solder bumps allow the die to be directly attached to the interposer 1104. The integrated circuit component 1120 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1120 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1120 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11, the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through silicon vias (TSV) extending through the silicon interposer can connect connections on a first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art. In embodiments where the interposer is a non-printed circuit board

The integrated circuit device assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit device assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include one or more of integrated circuit components comprising the three-input ferroelectric majority gates disclosed herein. Any suitable ones of the components of the electrical device 1200 may include one or more of the integrated circuit device assemblies 1100, integrated circuit components 1120, integrated circuit devices 900, or integrated circuit dies 802 disclosed herein. A number of components are illustrated in FIG. 12 as included in the electrical device 1200, but any one or more of these components may be omitted or duplicated, as suitable for the application. In some embodiments, some or all of the components included in the electrical device 1200 may be attached to one or more motherboards, mainboards, system boards, or other printed circuit boards. In some embodiments, one or more of these components are fabricated onto a single system-on-a-chip (SoC) die.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1218 or an audio output device 1208, but may include audio input or output device interface circuitry (e.g., connectors and supporting circuitry) to which an audio input device 1218 or audio output device 1208 may be coupled.

The electrical device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random-access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1200 can comprise one or more processor units 1202 that are heterogeneous or asymmetric to another processor unit 1202 in the electrical device 1200. There can be a variety of differences between the processing units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1212 may implement any of a number of wireless standards or protocols. In some embodiments, the communication component 1212 may manage wired communications, such as electrical, optical, or any other suitable communication protocols (e.g., IEEE 802.3 Ethernet standards).

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such speakers, headsets, or earbuds.

The electrical device 1200 may include another output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include an audio input device 1218 (or corresponding interface circuitry, as discussed above). The audio input device 1218 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1216 (or corresponding interface circuitry, as discussed above), such as a Global Positioning System (GPS) device.

The electrical device 1200 may include another output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include another input device 1220 (or corresponding interface circuitry, as discussed above). Examples of the other input device 1220 may include an accelerometer, a gyroscope, a compass, an image capture device (e.g., monoscopic or stereoscopic camera), a touchpad, a keyboard, a mouse, a stylus, or a touchscreen.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system. Further, the terms “computing device” and “computing system” as used herein are used interchangeably, and the term “apparatus” can refer to an electrical device, a computing device, or a computing system.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B, and C” can mean A; B; C; A and B; A and C; B and C; or A, B, and C.

As used in this application and the claims, the phrase “individual of” or “respective of” followed by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope comprises the apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus comprising: a first layer that is substantially planar, the first layer comprising a ferroelectric material; a first electrode, a second electrode, and a third electrode located on a top surface of the first layer, the first electrode having a first lateral area, the second electrode having a second lateral area, the first lateral area substantially equal to the second lateral area; a fourth electrode located on the top surface of the first layer, the fourth electrode located within a triangle having as its vertices a center of the first electrode, a center of the second electrode, and a center of the third electrode; and a fifth electrode, the first layer located on the fifth electrode.

Example 2 comprises the apparatus of Example 1, wherein the third electrode has a third lateral area that is less than the first lateral area.

Example 3 comprises the apparatus of Example 2, wherein the third lateral area is about half of the first lateral area.

Example 4 comprises the apparatus of any one of Examples 1-3, wherein the triangle is substantially an isosceles triangle.

Example 5 comprises the apparatus of any one of Examples 1-4, wherein the top surface is substantially square in shape.

Example 6 comprises the apparatus of Example 5, wherein the first electrode and the second electrode are located at adjacent corners along a first edge of the top surface, and the third electrode is located at a midpoint along a second edge of the top surface, the first edge opposite to the second edge.

Example 7 comprises the apparatus of Example 6, wherein the first electrode has a first length and a first width, the second electrode has a second length and a second width, the third electrode has a third length and a third width, the third length extending in a same direction as a direction of the second edge, wherein the first length, the first width, the second length, the second width, and the third width are substantially the same, wherein the third width is about half of the third length.

Example 8 comprises the apparatus of any one of Examples 1-7, wherein the fourth electrode is positioned substantially at a center of the triangle.

Example 9 comprises the apparatus of any one of Examples 1-7, wherein the fourth electrode is positioned substantially at a circumcenter, a centroid, or an incircle of the triangle.

Example 10 comprises the apparatus of any one of Examples 1-7, wherein the fourth electrode is positioned substantially at a center of the top surface.

Example 11 is an apparatus comprising: a first layer that is substantially planar, the first layer comprising a ferroelectric material, a top surface of the first layer having a square shape; a first electrode, a second electrode, and a third electrode located on the top surface of the first layer, the first electrode and the second electrode located at adjacent corners along a first edge of the top surface, the third electrode located at a midpoint of a second edge of the first layer, the second edge opposite to the first edge, the first electrode having a first length and a first width, the second electrode having a second length and a second width, the third electrode having a third length and a third width, the first length, the first width, the second length, the second width, and the third length substantially equal, the third width less than the first width; a fourth electrode located on the top surface of the first layer, the fourth electrode positioned within a triangle having as its vertices a center of the first electrode, a center of the second electrode, and a center of the third electrode; and a fifth electrode, the first layer located on the fifth electrode.

Example 12 comprises the apparatus of Example 11, wherein the third width is about half of the first width.

Example 13 comprises the apparatus of Example 11, wherein the fourth electrode is positioned substantially at a center of the triangle.

Example 14 comprises the apparatus of Example 11, wherein the fourth electrode is positioned substantially at a circumcenter, a centroid, or an incircle of the triangle.

Example 15 comprises the apparatus of Example 11, wherein the first electrode, the second electrode, and the third electrode are substantially one-third as wide as the first layer.

Example 16 is an apparatus comprising: a first layer that is substantially planar, the first layer comprising a ferroelectric material, a top surface of the first layer having a substantially circular shape or an elongated rectangular shape; a first electrode, a second electrode, and a third electrode having substantially the same size and shape, the first electrode, the second electrode, and the third electrode positioned on the top surface of the first layer; a fourth electrode located on the top surface of the first layer; and a fifth electrode, the first layer located on the fifth electrode.

Example 17 comprises the apparatus of Example 16, wherein the first electrode, the second electrode, and the third electrode are arranged in a triangular configuration and the fourth electrode is located substantially at a center of a triangle having as its vertices a center of the first electrode, a center of the second electrode, and a center of the third electrode.

Example 18 comprises the apparatus of Example 17, wherein the center is a circumcenter, a centroid, or an incircle of the triangle.

Example 19 comprises the apparatus of any one of Examples 16-18, wherein the top surface of the first layer, a top surface of the first electrode, a top surface of the second electrode, and a top surface of the third electrode have a substantially circular shape.

Example 20 comprises the apparatus of Example 19, wherein the first electrode, the second electrode, and the third electrode are substantially equidistant from one another.

Example 21 comprises the apparatus of any one of Examples 16-18, wherein the top surface of the first layer has a substantially elongated shape.

Example 22 comprises the apparatus of Example 21, wherein the first electrode and the second electrode are positioned at adjacent corners along a first edge of the top surface and the third electrode is positioned at a midpoint of a second edge of the top surface, the second edge opposite to the first edge.

Example 23 comprises the apparatus of Example 22, wherein the first edge extends in a direction and the first layer is elongated in the direction.

Example 24 comprises the apparatus of Example 22, wherein the first edge extends in a direction and the first layer is elongated in a direction substantially orthogonal to the direction.

Example 25 comprises the apparatus of any one of Examples 16-18, wherein the first electrode, the second electrode, and the third electrode are the fourth electrode are positioned in a row on the top surface of the first layer, the fourth electrode positioned at an end of the row.

Example 26 is an apparatus comprising: a first layer that is substantially planar, the first layer comprising a ferroelectric material, the first layer having a cross shape, the first layer having a first end, a second end, a third end, and a fourth end; a first electrode positioned on a top surface of the first layer at the first end; a second electrode positioned on the top surface of the first layer at the second end; a third electrode positioned on the top surface of the first layer at the third end; a fourth electrode positioned on the top surface of the first layer at the fourth end; and a fifth electrode located on a bottom surface of the first layer.

Example 27 comprises the apparatus of any one of Examples 1-26, wherein a lateral area of the fourth electrode is less than a lateral area of the first electrode and the second electrode.

Example 28 comprises the apparatus of any one of Examples 1-27, wherein a thickness of the first layer is about 10 nanometers or less.

Example 29 comprises the apparatus of any one of Examples 1-27, wherein a thickness of the first layer is about 6 nanometers or less.

Example 30 comprises the apparatus of any one of Examples 1-27, wherein a thickness of the first layer is about 2 nanometers.

Example 31 comprises the apparatus of any one of Examples 1-30, wherein the first layer has a length and a width of about 30 nanometers or less.

Example 32 comprises the apparatus of any one of Examples 1-30, wherein the first layer has a length and a width of about 10 nanometers or less.

Example 33 comprises the apparatus of any one of Examples 1-32, wherein the ferroelectric material comprises lead, strontium, and titanium.

Example 34 comprises the apparatus of any one of Examples 1-32, wherein the ferroelectric material comprises barium, titanium, and oxygen.

Example 35 comprises the apparatus of any one of Examples 1-32, wherein the ferroelectric material comprises bismuth, iron, and oxygen.

Example 36 comprises the apparatus of Example 35, wherein the ferroelectric material further comprises samarium.

Example 37 comprises the apparatus of Example 35, wherein the ferroelectric material further comprises lanthanum.

Example 38 comprises the apparatus of any one of Examples 1-32, wherein the ferroelectric material comprises lithium, tantalum, and oxygen.

Example 39 comprises the apparatus of any one of Examples 1-32, wherein the ferroelectric material comprises lead, zirconium, titanium, and oxygen.

Example 40 comprises the apparatus of any one of Examples 1-32, wherein the ferroelectric material comprises lead, niobium, zirconium, titanium, and oxygen.

Example 41 comprises the apparatus of any one of Examples 1-32, wherein the ferroelectric material comprises lead, lanthanum, zirconium, titanium, and oxygen.

Example 42 comprises the apparatus of any one of Examples 1-32, wherein the ferroelectric material comprises sodium, tantalum, and oxygen.

Example 43 comprises the apparatus of any one of Examples 1-32, wherein the ferroelectric material comprises strontium, titanium, and oxygen.

Example 44 comprises the apparatus of any one of Examples 1-32, wherein the ferroelectric material comprises potassium, tantalum, and oxygen.

Example 45 comprises the apparatus of any one of Examples 1-32, wherein the ferroelectric material comprises barium, strontium, titanium, and oxygen.

Example 46 comprises the apparatus of any one of Examples 1-32, wherein the ferroelectric material comprises tantalum and oxygen.

Example 47 comprises the apparatus of any one of Examples 1-32, wherein the ferroelectric material comprises bismuth, iron, cobalt, and oxygen.

Example 48 comprises the apparatus of any one of Examples 1-32, wherein the ferroelectric material comprises potassium, sodium, and oxygen.

Example 49 comprises the apparatus of any one of Examples 1-32, wherein the ferroelectric material comprises calcium, niobium, titanium, and oxygen.

Example 50 comprises the apparatus of any one of Examples 1-32, wherein the ferroelectric material comprises lead, bismuth, niobium, and oxygen.

Example 51 comprises the apparatus of any one of Examples 1-32, wherein the ferroelectric material comprises calcium, niobium, nitrogen, and oxygen.

Example 52 comprises the apparatus of any one of Examples 1-32, wherein the ferroelectric material comprises bismuth, titanium, and oxygen.

Example 53 comprises the apparatus of any one of Examples 1-32, wherein the ferroelectric material comprises lead, titanium, and oxygen.

Example 54 comprises the apparatus of any one of Examples 1-32, wherein the ferroelectric material comprises barium, hafnium, titanium, and oxygen.

Example 55 comprises the apparatus of any one of Examples 1-32, wherein the ferroelectric material comprises barium, calcium, zirconium, titanium, and oxygen.

Example 56 comprises the apparatus of any one of Examples 1-32, wherein the ferroelectric material comprises gadolinium, iron, and oxygen.

Example 57 comprises the apparatus of any one of Examples 1-32, wherein the ferroelectric material comprises gadolinium, lanthanum, iron, and oxygen.

Example 58 comprises the apparatus of any one of Examples 1-32, wherein the ferroelectric material comprises tungsten and oxygen.

Example 59 comprises the apparatus of any one of Examples 1-32, wherein the ferroelectric material comprises barium, zirconium, titanium, and oxygen.

Example 60 comprises the apparatus of any one of Examples 1-32, wherein the ferroelectric material comprises barium, zirconium, titanium, and oxygen.

Example 61 comprises the apparatus of any one of Examples 1-60, wherein the first electrode comprises lanthanum, strontium, manganese, and oxygen.

Example 62 comprises the apparatus of any one of Examples 1-60, wherein the first electrode comprises niobium, strontium, titanium, and oxygen.

Example 63 comprises the apparatus of any one of Examples 1-60, wherein the first electrode comprises strontium, ruthenium, and oxygen.

Example 64 comprises the apparatus of any one of Examples 1-60, wherein the first electrode comprises a metal or an alloy.

Example 65 comprises the apparatus of any one of Examples 1-64, wherein the fifth electrode comprises strontium, ruthenium, and oxygen.

Example 66 comprises the apparatus of any one of Examples 1-64, wherein the fifth electrode comprises a metal or an alloy.

Example 67 comprises the apparatus of any one of Examples 1-64, wherein the fifth electrode comprises lanthanum, strontium, manganese, and oxygen.

Example 68 comprises the apparatus of any one of Examples 1-64, wherein the fifth electrode comprises niobium, strontium, titanium, and oxygen.

Example 69 comprises the apparatus of any one of Examples 1-64, the apparatus further comprising: a first via located on the fourth electrode, the first via comprising a metal; a second via located on the fourth electrode, the second via comprising the metal; a first output electrode located above a top surface of the ferroelectric layer and connected to the fourth electrode by the first via; and a second output electrode located above the top surface of the ferroelectric layer and connected to the fourth electrode by the second via.

Example 70 comprises the apparatus of Example 69, wherein the fourth electrode comprises a transition metal dichalcogenide.

Example 71 comprises the apparatus of Example 69, wherein the fourth electrode comprises: germanium and oxygen; indium and oxygen; zinc and oxygen; or barium, tin, and oxygen.

Example 72 comprises the apparatus of Example 69, wherein the first output electrode and the second output electrode comprise the metal.

Example 73 comprises the apparatus of Example 69, wherein first output electrode and the second output electrode comprise copper.

Example 74 comprises the apparatus of any one of Examples 1-73, wherein the fourth electrode substantially covers a bottom surface of the first layer.

Example 75 comprises the apparatus of any one of Examples 1-74, wherein the apparatus comprises an integrated circuit component, the integrated circuit component comprising the first layer.

Example 76 comprises the apparatus of Example 75 further comprising a printed circuit board, the integrated circuit component attached to the printed circuit board.

Example 77 comprises the apparatus of Example 76 wherein the integrated circuit component is a first integrated circuit component, the apparatus further comprising a second integrated circuit component attached to the printed circuit board.

Example 78 is a method comprising: forming a bottom electrode comprising a first material; forming a layer on the bottom electrode, the layer substantially planar and comprising a ferroelectric material, a top surface of the bottom electrode having a square shape; and forming a first electrode, a second electrode, a third electrode, and a fourth electrode on the top surface of the layer, the first electrode having a first lateral area, the second electrode having a second lateral area, the first lateral area substantially equal to the second lateral area, the fourth electrode located on the top surface of the layer, the fourth electrode positioned within a triangle having as its vertices a center of the first electrode, a center of the second electrode, and a center of the third electrode.

Example 79 comprises the method of Example 78, wherein the fourth electrode is positioned substantially at a center of the triangle.

Example 80 comprises the method of Example 79, wherein the fourth electrode is positioned substantially at a circumcenter, a centroid, or an incircle of the triangle.

Example 81 comprises the method of Example 78, wherein the fourth electrode is positioned substantially at a center of the top surface.

Example 82 comprises the method of any one of Examples 78-81, wherein a lateral area of the fourth electrode is less than a lateral area of the first electrode.

Example 83 comprises the method of Example 82, wherein the third of the fourth electrode is about half of the lateral area of the first electrode.

Example 84 comprises the method of any one of Examples 78-83, wherein the top surface is substantially square in shape.

Example 85 comprises the method of Example 84, wherein the first electrode and the second electrode are located at adjacent corners along a first edge of the top surface, and the third electrode is located at a midpoint along a second edge of the top surface, the first edge opposite to the second edge.

Example 86 comprises the method of Example 85, wherein the first electrode has a first length and a first width, the second electrode has a second length and a second width, the third electrode has a third length and a third width, the third length extending in a same direction as a direction of the second edge, wherein the first length, the first width, the second length, the second width, and the third width are substantially the same, wherein the third width is about half of the third length.

Example 87 comprises the method of any one of Examples 78-86, wherein the ferroelectric material comprises: lead, strontium, and titanium; barium, titanium, and oxygen; bismuth, iron, and oxygen; samarium; lanthanum; lithium, tantalum, and oxygen; lead, zirconium, titanium, and oxygen; lead, niobium, zirconium, titanium, and oxygen; lead, lanthanum, zirconium, titanium, and oxygen; sodium, tantalum, and oxygen; strontium, titanium, and oxygen; potassium, tantalum, and oxygen; barium, strontium, titanium, and oxygen; tantalum and oxygen; bismuth, iron, cobalt, and oxygen; potassium, sodium, and oxygen; calcium, niobium, titanium, and oxygen; lead, bismuth, niobium, and oxygen; calcium, niobium, nitrogen, and oxygen; bismuth, titanium, and oxygen; lead, titanium, and oxygen; barium, hafnium, titanium, and oxygen; barium, calcium, zirconium, titanium, and oxygen; gadolinium, iron, and oxygen; gadolinium, lanthanum, iron, and oxygen; tungsten and oxygen; barium, zirconium, titanium, and oxygen; or barium, zirconium, titanium, and oxygen.

Example 88 comprises the method of any one of Examples 78-87, wherein the first electrode comprises: lanthanum, strontium, manganese, and oxygen; comprises niobium, strontium, titanium, and oxygen; or comprises strontium, ruthenium, and oxygen.

Example 89 comprises the method of any one of Examples 78-88, wherein the bottom electrode comprises: lanthanum, strontium, manganese, and oxygen; comprises niobium, strontium, titanium, and oxygen; or comprises strontium, ruthenium, and oxygen.

Example 90 comprises the method of any one of Examples 78-87, wherein the first electrode and the bottom electrode comprise a metal or an alloy.

Example 91 comprises the method of any one of Examples 78-87, wherein the bottom electrode substantially covers a bottom surface of the layer.

Example 92 comprises the method of any one of Examples 78-91, further comprising forming the bottom electrode on a substrate, the substrate comprising: silicon; or silicon and oxygen.

1. An apparatus comprising:
a first layer that is substantially planar, the first layer comprising a ferroelectric material;
a first electrode, a second electrode, and a third electrode located on a top surface of the first layer, the first electrode having a first lateral area, the second electrode having a second lateral area, the third electrode having a third lateral area, the first lateral area substantially equal to the second lateral area, the third lateral area less than the first lateral area;
a fourth electrode located on the top surface of the first layer, the fourth electrode located within a triangle having as its vertices a center of the first electrode, a center of the second electrode, and a center of the third electrode; and
a fifth electrode, the first layer located on the fifth electrode.

2. The apparatus of claim 1, wherein the first electrode and the second electrode are located at adjacent corners along a first edge of the top surface, and the third electrode is located at a midpoint along a second edge of the top surface, the first edge opposite to the second edge.

3. The apparatus of claim 2, wherein the first electrode has a first length and a first width, the second electrode has a second length and a second width, the third electrode has a third length and a third width, the third length extending in a same direction as a direction of the second edge, wherein the first length, the first width, the second length, the second width, and the third width are substantially the same, wherein the third width is about half of the third length.

4. The apparatus of claim 1, wherein the third electrode has a third lateral area that is less than the first lateral area.

5. The apparatus of claim 1, wherein the ferroelectric material comprises:
lead, strontium, and titanium;
barium, titanium, and oxygen;
bismuth, iron, and oxygen;
further comprises samarium or lanthanum;
lithium, tantalum, and oxygen;
lead, zirconium, titanium, and oxygen;
lead, niobium, zirconium, titanium, and oxygen;
lead, lanthanum, zirconium, titanium, and oxygen;
sodium, tantalum, and oxygen;
strontium, titanium, and oxygen;
potassium, tantalum, and oxygen;
barium, strontium, titanium, and oxygen;
tantalum and oxygen;
bismuth, iron, cobalt, and oxygen;
potassium, sodium, and oxygen;
calcium, niobium, titanium, and oxygen;
lead, bismuth, niobium, and oxygen;
calcium, niobium, nitrogen, and oxygen;
bismuth, titanium, and oxygen;
lead, titanium, and oxygen;
barium, hafnium, titanium, and oxygen;
barium, calcium, zirconium, titanium, and oxygen;
gadolinium, iron, and oxygen;
gadolinium, lanthanum, iron, and oxygen;
tungsten and oxygen;
barium, zirconium, titanium, and oxygen; or
barium, zirconium, titanium, and oxygen.

6. The apparatus of claim 1,
wherein the first electrode comprises:
lanthanum, strontium, manganese, and oxygen;
niobium, strontium, titanium, and oxygen; or
strontium, ruthenium, and oxygen; and
wherein the first electrode comprises:
lanthanum, strontium, manganese, and oxygen;
niobium, strontium, titanium, and oxygen; or
strontium, ruthenium, and oxygen.

7. The apparatus of claim 1, further comprising:
a first integrated circuit component comprising the first layer;
a second integrated circuit component; and
a printed circuit board, the first integrated circuit component and the second integrated circuit component attached to the printed circuit board.

8. An apparatus comprising:
a first layer that is substantially planar, the first layer comprising a ferroelectric material, a top surface of the first layer having a square shape;
a first electrode, a second electrode, and a third electrode located on the top surface of the first layer, the first electrode and the second electrode located at adjacent corners along a first edge of the top surface, the third electrode located at a midpoint of a second edge of the first layer, the second edge opposite to the first edge, the first electrode having a first length and a first width, the second electrode having a second length and a second width, the third electrode having a third length and a third width, the first length, the first width, the second length, the second width, and the third length substantially equal, the third width less than the first width;
a fourth electrode located on the top surface of the first layer, the fourth electrode positioned within a triangle having as its vertices a center of the first electrode, a center of the second electrode, and a center of the third electrode; and
a fifth electrode, the first layer located on the fifth electrode.

9. The apparatus of claim 8, wherein the third width is about half of the first width.

10. The apparatus of claim 8, wherein the fourth electrode is positioned substantially at a center of the triangle.

11. The apparatus of claim 8, wherein the ferroelectric material comprises:
lead, strontium, and titanium;
barium, titanium, and oxygen;
bismuth, iron, and oxygen;
further comprises samarium or lanthanum;
lithium, tantalum, and oxygen;
lead, zirconium, titanium, and oxygen;
lead, niobium, zirconium, titanium, and oxygen;
lead, lanthanum, zirconium, titanium, and oxygen;
sodium, tantalum, and oxygen;
strontium, titanium, and oxygen;
potassium, tantalum, and oxygen;
barium, strontium, titanium, and oxygen;
tantalum and oxygen;
bismuth, iron, cobalt, and oxygen;
potassium, sodium, and oxygen;
calcium, niobium, titanium, and oxygen;
lead, bismuth, niobium, and oxygen;
calcium, niobium, nitrogen, and oxygen;
bismuth, titanium, and oxygen;
lead, titanium, and oxygen;
barium, hafnium, titanium, and oxygen;
barium, calcium, zirconium, titanium, and oxygen;
gadolinium, iron, and oxygen;
gadolinium, lanthanum, iron, and oxygen;
tungsten and oxygen;
barium, zirconium, titanium, and oxygen; or
barium, zirconium, titanium, and oxygen.

12. The apparatus of claim 8,
wherein the first electrode comprises:
lanthanum, strontium, manganese, and oxygen;
niobium, strontium, titanium, and oxygen; or
strontium, ruthenium, and oxygen; and
wherein the first electrode comprises:
lanthanum, strontium, manganese, and oxygen;
niobium, strontium, titanium, and oxygen; or
strontium, ruthenium, and oxygen.

13. The apparatus of claim 8, further comprising:
a first integrated circuit component comprising the first layer;
a second integrated circuit component; and
a printed circuit board, the first integrated circuit component and the second integrated circuit component attached to the printed circuit board.

14. An apparatus comprising:
a first layer that is substantially planar, the first layer comprising a ferroelectric material, a top surface of the first layer having a substantially circular shape or an elongated rectangular shape;
a first electrode, a second electrode, and a third electrode having substantially the same size and shape, the first electrode, the second electrode, and the third electrode positioned on the top surface of the first layer;
a fourth electrode located on the top surface of the first layer; and
a fifth electrode, the first layer located on the fifth electrode.

15. The apparatus of claim 14, wherein the first electrode, the second electrode, and the third electrode are arranged in a triangular configuration and the fourth electrode is located substantially at a center of a triangle having as its vertices a center of the first electrode, a center of the second electrode, and a center of the third electrode.

16. The apparatus of claim 14, wherein the top surface of the first layer, a top surface of the first electrode, a top surface of the second electrode, and a top surface of the third electrode have a substantially circular shape.

17. The apparatus of claim 14, wherein the top surface of the first layer has a substantially elongated rectangular shape.

18. The apparatus of claim 17, wherein the first electrode and the second electrode are positioned at adjacent corners along a first edge of the top surface and the third electrode is positioned at a midpoint of a second edge of the top surface, the second edge opposite to the first edge.

19. The apparatus of claim 14, wherein the first electrode, the second electrode, and the third electrode are the fourth electrode are positioned in a row on the top surface of the first layer, the fourth electrode positioned at an end of the row.

20. The apparatus of claim 14, wherein the ferroelectric material comprises:
lead, strontium, and titanium;
barium, titanium, and oxygen;
bismuth, iron, and oxygen;
further comprises samarium or lanthanum;
lithium, tantalum, and oxygen;
lead, zirconium, titanium, and oxygen;
lead, niobium, zirconium, titanium, and oxygen;
lead, lanthanum, zirconium, titanium, and oxygen;
sodium, tantalum, and oxygen;
strontium, titanium, and oxygen;
potassium, tantalum, and oxygen;
barium, strontium, titanium, and oxygen;
tantalum and oxygen;
bismuth, iron, cobalt, and oxygen;
potassium, sodium, and oxygen;
calcium, niobium, titanium, and oxygen;
lead, bismuth, niobium, and oxygen;
calcium, niobium, nitrogen, and oxygen;
bismuth, titanium, and oxygen;
lead, titanium, and oxygen;
barium, hafnium, titanium, and oxygen;
barium, calcium, zirconium, titanium, and oxygen;
gadolinium, iron, and oxygen;
gadolinium, lanthanum, iron, and oxygen;
tungsten and oxygen;
barium, zirconium, titanium, and oxygen; or
barium, zirconium, titanium, and oxygen.
